(19) United States
(12) Patent Application Publication
(10) Pub. No.: US 2020/0256751 A1
(43) Pub. Date: Aug. 13, 2020

(54) Pressure Sensor on Ceramic Pressure Connections

(71) Applicant: TDK Electronics AG, Munich (DE)

(72) Inventors: Benjamin Bohl, Berlin (DE); Jan Ihle, Raaba-Grambach (AT); Bert Hundertmark, Stahnsdorf (DE); Bernd Polder, Berlin (DE); Christian Wohlgemuth, Berlin (DE)

(21) Appl. No.: 16/629,663

(22) PCT Filed: Sep. 27, 2018
(86) PCT No.: PCT/EP2018/076313

§ 371 Date: Jan. 9, 2020

(30) Foreign Application Priority Data
Sep. 28, 2017 (DE) 102017122631.1

(51) Int. Cl. G01L 19/04; B81B 7/02; H05B 1/02

(52) U.S. Cl. CPC G01L 19/04; B81B 2201/0264; H05B 1/0236; B81B 7/02

(57) ABSTRACT

A pressure sensor is disclosed. In an embodiment a pressure sensor includes a housing having a housing wall, a sensor element arranged in the housing, a ceramic substrate configured to serve as a support for the sensor element and an electrical connection thereof and a first heating element arranged in an interior of the housing or in the housing wall.

### CROSS-REFERENCE TO RELATED APPLICATIONS

This patent application is a national phase filing under section 371 of PCT/EP2018/076313, filed Sep. 27, 2018, which claims the priority of German patent application 10 2017 122 631.1, filed Sep. 28, 2017, each of which is incorporated herein by reference in its entirety.

### TECHNICAL FIELD

This relates to a MEMS pressure sensor for deployment in freezing or high-viscosity media, in particular for deployment in automotive engineering.

### BACKGROUND

It can happen that condensate, freezing or high-viscosity media falsify a measuring signal from pressure sensors. These are inter alia hot, viscous, low-viscosity cold, aqueous or oily phases, cold viscous oils, frozen water or fuel. The consequences of a falsified measurement can be: insufficient exhaust gas purification, engine damage or generally damage to other elements of a process which is to be monitored. Due to the increased requirement for keeping the exhaust gases of internal combustion engines clean, it is e.g. necessary to perform exact pressure measurements immediately after starting an engine from cold.

### SUMMARY

Embodiments provide a pressure sensor which can already perform a correct pressure measurement shortly after starting the engine from cold and can increase the life of the pressure sensor.

Embodiments provide a pressure sensor with which it is possible to measure relative or absolute pressures. Said sensor comprises a housing which in turn comprises a housing wall. The housing wall can be sealed for measuring an absolute pressure and can contain openings for measuring the relative pressure, in order to e.g. use atmospheric conditions as the reference pressure. The following are arranged in the housing: a sensor element and a ceramic substrate.

The sensor element is a component, with which a pressure-related deflection of a membrane is determined. It can be designed in different technical variants: e.g. a direct pressure determination utilizing the piezo effect or by means of measuring the elongation of the membrane with the aid of e.g. resistance elements. For the orientation of the sensor element, the side of the sensor element on which the membrane is located is designated below as the upper side of the sensor element and the opposite side is designated as the lower side of the sensor element.

The ceramic substrate serves as a support for the sensor element and the electrical connection thereof. To this end, the electrical connection on the ceramic substrate serves to conduct a measuring signal from the pressure sensor, where it is externally processed and a pressure is assigned to the signal. The sensor element is connected to the ceramic substrate so that both the upper side and the lower side are accessible for different media. The sensor element can be configured as a MEMS component.

Moreover, a heating element is part of the pressure sensor. It can be mounted at different positions in the pressure sensor with the purpose of attaining an operating temperature in the pressure sensor, which allows an exact measurement. Thanks to the heating up of the pressure sensor, possible solid and liquid condensates are thawed, if applicable evaporated and expelled together with any existing high-viscosity media out of the pressure sensor, or respectively are baked out. It is also possible to prevent a formation of ice crystals which can damage or destroy the sensor element with the heating element.

The pressure sensor comprises a small glass/ceramic tube which is arranged on the lower side of the sensor element. The small glass/ceramic tube serves to supply the media to the sensor element and is guided through the housing wall, wherein the medium in the interior of the small glass/ceramic tube is transported to the lower side of the sensor element, or respectively can come into contact with the sensor there. The pressure in the medium is then also applied to the sensor element. The medium can be enclosed in a closed system outside of the sensor. With the small glass/ceramic tube, a thermal bridge between the sensor element and the system to be monitored is created and the media properties, pressure and temperature, of the system to be measured are transferred to the sensor element. The small glass/ceramic tube serves to seal the pressure measurement in an improved manner.

The pressure sensor comprises a gel filling which is mounted in a gel delimitation on the ceramic substrate and is mounted on the upper side of the sensor element. The gel delimitation is a container which is open at the top and at the bottom, which terminates with the membrane of the sensor element on its upper side and can be filled from above with a gel. The gel filling transfers the atmospheric pressure from the interior of the housing to the membrane of the sensor element and thereby itself fulfils the function of a membrane. Thanks to the gel filling, the upper side of the sensor element is protected, e.g. against the influences of humidity in the atmosphere.

The heating element is, for example, configured to warm the pressure sensor to a temperature which is clearly above the freezing point. For example, warming to a temperature between 20° C. and 50° C., in particular up to 160° C., is envisaged.

The heating element can be mounted at many different positions. These are all situated in the interior of the pressure sensor and are indicated below in a non-exhaustive list:

The heating element can be arranged:

in or on the ceramic substrate (positions A and B), wherein the heating element is, in this case, preferably mounted in the vicinity of the electrical connections. The ceramic substrate can also be configured as a laminated ceramic. The heating element can, for example, be pressed onto a layer in the interior or on a surface of the ceramic substrate;

in the housing, e.g., internally on the housing wall (position C), wherein the heating element is in direct contact with components of the housing thanks to adhesion, clamping or soldering;

inside the housing wall (position D);

in or on the small glass/ceramic tube (positions E and F); or

on the gel delimitation (position G). The heating element can also be integrated into the gel delimitation.

The different embodiments of the heating element can comprise: a conductive plastic, a resistor which is formed e.g. as a meander or a resistor having positive temperature coefficients. The advantage of a possible meander shape of the resistor is that the resistor is longer and consequently has a higher value, which results in a higher heating capacity. It is no longer necessary to regulate a heating capacity of the heating element externally when a resistor having positive temperature coefficients is used.

In a further embodiment, the heating element is integrated into the housing of the sensor and can radiate microwaves, with which the media to be measured are heated. As a result, the warming takes place directly in the medium and the heating capacity is utilized in a more optimum manner. Such a heating element can also be arranged at another location of the sensor.

The heating capacity can be supplied by means of different routes. There is e.g. the possibility of by means of the power supply of the pressure sensor, and the variant of an additional power supply which is independent of the sensor element. The advantage of separating the energy supply is that the measuring signals are not adversely affected.

In addition to the described heating element, the pressure sensor can comprise a further heating element in one of the explained construction forms. This can be mounted at one of the described positions, which is however different from the position of the first heating element. Thanks to the deployment of multiple heating elements, the pressure sensor can be heated up more homogeneously and, consequently, more efficiently.

The pressure sensor described previously is, for example, configured for use in a motor vehicle, in particular for deployment in the exhaust region of a motor vehicle, e.g. in the region of a diesel particulate sensor or a urea sensor.

According to a further embodiment, a method for operating the previously described pressure sensor is indicated. According to the method, during commissioning of the pressure sensor, the heating element is switched on in order to heat up the pressure sensor until a fixed operating temperature is attained. A first pressure measurement is effected at the fixed operating temperature. In order to lower the energy consumption, the heating element is turned on for heating, for example, as little as possible during the operation of the pressure sensor. For example, the heating element is switched off when the operating temperature is attained. A freezing of the pressure sensor is subsequently prevented by the engine heat. Alternatively, permanent operation of the heating element is also possible in order to prevent freezing during driving.

### BRIEF DESCRIPTION OF THE DRAWINGS

The invention and its component parts are explained in greater detail below with reference to a selection of exemplary embodiments and the accompanying schematic figures.

FIG. 1 shows a schematic sectional view of a pressure sensor DS having different positions for one or more heating elements and their relative relationship to other component parts of the pressure sensor; and

FIG. 2 shows a schematic sectional view of a sensor element.

### DETAILED DESCRIPTION OF ILLUSTRATIVE EMBODIMENTS

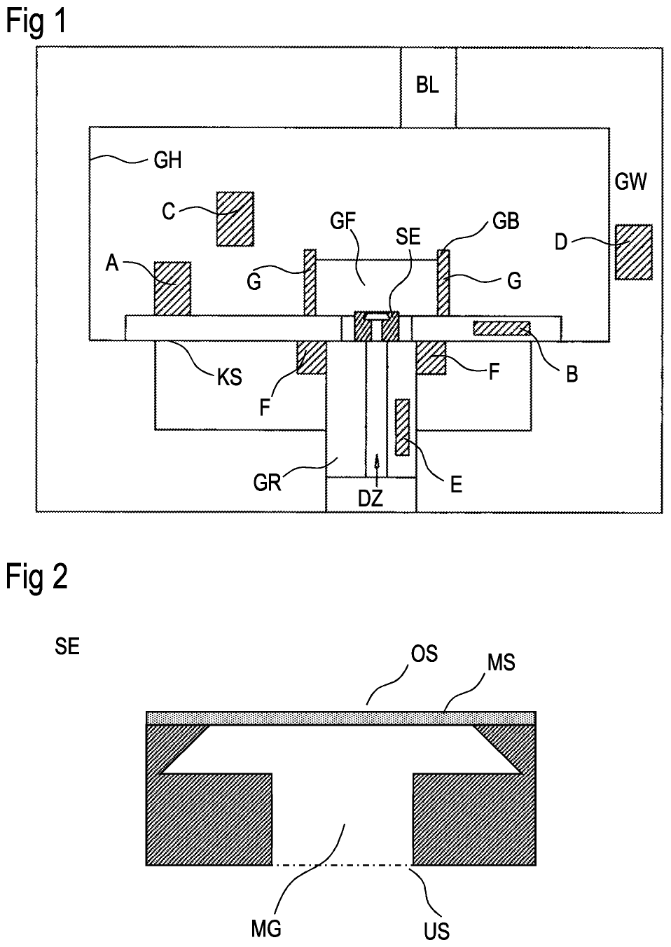

The sectional view shown in FIG. 1 shows the schematic construction of a pressure sensor. Said sensor has a housing GH comprising a housing wall GW, a ceramic substrate KS located inside the housing, a sensor element SE embedded in the ceramic substrate, a small glass/ceramic tube GR on the lower side of the sensor element and a gel filling GF in a gel delimitation GB on the upper side of the sensor element.

In addition, multiple different variants for the possible positioning of one or more heating elements H, in particular at the positions A to G, are drawn in. The drawn-in exemplary mounting locations of the heating element are as follows: the heating element can be arranged in or on the ceramic substrate (positions A and B);

in the housing, e.g. internally on the housing wall (position C);

inside the housing wall (position D);

in or on the small glass/ceramic tube (positions E and F); or

on the gel delimitation (position G).

All the representations of the positions of the heating element are purely schematic and are not to scale with respect to one another or to the size of the respectively represented components.

FIG. 2 shows an enlarged sectional view of the sensor element SE. Here, a membrane of the sensor element MS can be seen, which forms the upper side OS of the sensor element in this case. Opposite the upper side, a lower side US of the sensor element is arranged, in which a media passage MG to the membrane of the sensor element MS is located.

The form of the sensor element is only represented by way of example in FIGS. 1 and 2. Other forms or materials can also be used to construct a sensor element.

1-18. (canceled)

19. A pressure sensor comprising:
a housing comprising a housing wall;
a sensor element arranged in the housing;
a ceramic substrate configured to serve as a support for the sensor element and an electrical connection thereof; and
a first heating element arranged in an interior of the housing or in the housing wall.

20. The pressure sensor according to claim 19, wherein the first heating element is arranged in a position on or in a position in the ceramic substrate.

21. The pressure sensor according to claim 19, wherein the first heating element is arranged in the interior of the housing.

22. The pressure sensor according to claim 19, further comprising a small glass/ceramic tube configured to supply a medium, wherein the small tube is mounted on a lower side of the sensor element.

23. The pressure sensor according to claim 19, wherein the sensor element is connected to the ceramic substrate so that different media lie in contact with an upper side and a lower side of the sensor element in each case.

24. The pressure sensor according to claim 19, wherein the first heating element is arranged in or on a small glass/ceramic tube which is located on a lower side of the sensor element.

25. The pressure sensor according to claim 19, further comprising a gel filling having a gel delimitation as a protection of a membrane on an upper side of the sensor element, wherein the first heating element is arranged on the gel delimitation.

26. The pressure sensor according to claim 19, wherein the first heating element comprises an electrically conductive plastic.

27. The pressure sensor according to claim 19, wherein the first heating element comprises a resistance element having a positive temperature coefficient.

28. The pressure sensor according to claim 19, wherein the first heating element is integrated into parts of the housing wall and is suitable for producing microwave radiation.

29. The pressure sensor according to claim 19, wherein the first heating element is equipped with a power supply which is separated from the pressure sensor.

30. The pressure sensor according to claim 19, wherein the sensor element is a MEMS component.

31. The pressure sensor according to claim 19, further comprising a second heating element arranged at a different location from the first heating element.

32. The pressure sensor according to claim 19, wherein the pressure sensor is configured to measure a pressure when starting an engine in a motor vehicle from cold, wherein the first heating element is configured to warm the pressure sensor up to a fixed operating temperature, at which a first pressure measurement is effected.

33. The pressure sensor according to claim 19, wherein the first heating element is configured to warm up to a temperature between 20° C. and 160° C.

34. A method comprising:
using the pressure sensor according to claim 19 in a motor vehicle.

35. A method for operating the pressure sensor according to claim 19, the method comprising:
switching on the first heating element, while commissioning the pressure sensor, in order to heat up the pressure sensor until a fixed operating temperature is attained.

36. The method according to claim 35, further comprising switching off the first heating element when the operating temperature is attained.
